(19) United States
(12) Patent Application Publication
(10) Pub. No.: US 2024/0178184 A1
(43) Pub. Date: May 30, 2024

(54) PROXIMITY SENSOR

(71) Applicant: Texas Instruments Incorporated, Dallas, TX (US)

(72) Inventors: Sreenivasan Kalyani KODURI, DALLAS, TX (US); Leslie Edward STARK, Heath, TX (US)

(73) Assignee: Texas Instruments Incorporated, Dallas, TX (US)

(21) Appl. No.: 18/433,047

(22) Filed: Feb. 5, 2024

Related U.S. Application Data
(62) Division of application No. 17/121,198, filed on Dec. 14, 2020, now Pat. No. 11,894,339.

(51) Int. Cl. H01L 25/04; G01S 17/08; H01L 25/075; H01L 33/62

(52) U.S. Cl. CPC H01L 25/042; G01S 17/08; H01L 25/0753; H01L 33/62

(57) ABSTRACT

A packaged integrated circuit (IC), comprising: a lead frame; one or more semiconductor dies on the lead frame, the one or more semiconductor dies including a first circuit and a second circuit; and a molding compound encapsulating the lead frame and the semiconductor die, the molding compound including a first cavity over the first circuit and a second cavity over the second circuit, in which at least one of the first or second cavities includes a second material different from the molding compound.

### CROSS-REFERENCE TO RELATED APPLICATIONS

This nonprovisional application is a continuation of U.S. patent application Ser. No. 17/121,198, filed Dec. 14, 2020, which is hereby incorporated by reference in its entirety.

### BACKGROUND

Many proximity sensors include a transmitter and a receiver. The transmitter transmits a signal, for example an optical signal or a radar signal, and the receiver receives reflections of the transmitted signal. The time between signal transmission and receipt of the reflected signal can be used to determine the distance between the proximity sensor and the object off of which the transmitted signal was reflected. Channel isolation between the transmitter and receiver is important to achieving precise measurements. Some sensing systems also require complex calibration calibrations to determine the precise location of the transmitter and receiver relative to each other. Also, optical sensing systems require careful alignment of optical components, which can increase the size of the sensing system. Some sensing systems attempt to place the transmitter and receiver in a single package to ensure a fixed spatial relationship. However, building a transmitter and a receiver into a single sensor package is complex, and the resulting sensor package is often not as small as desired for a particular implementation.

### SUMMARY

A method of manufacturing a sensor device includes obtaining a semiconductor die structure comprising a transmitter and a receiver. Then, a first sacrificial stud is affixed to the transmitter, and a second sacrificial stud is affixed to the receiver. The semiconductor structure is affixed to a lead frame, and pads on the semiconductor structure are wirebonded to the lead frame. The lead frame, the semiconductor structure, and the wirebonds are encapsulated in a molding compound, while the tops of the first and second sacrificial studs are left exposed. The first and second sacrificial studs prevent the molding compound from encapsulating the transmitter and the receiver, and are removed to expose the transmitter in a first cavity and the receiver in a second cavity.

In some examples, the semiconductor structure comprises a single semiconductor die with both the transmitter and the receiver. In some examples, the semiconductor structure comprises two semiconductor die, a first semiconductor die comprising the transmitter and a second semiconductor die comprising the receiver. In some implementations, the first and second cavities are filled with a non-molding compound material, such as a clear plastic, lenses, and the like. For example, the transmitter comprises a light source, and the receiver comprises a light detector. The first and second cavities are filled with a transparent compound to allow light to pass through from the light source and to the light detector. The molding compound forms a barrier between the first and second cavities in some examples.

In some implementations, the first and second sacrificial studs are tapered. In some examples, the first and second sacrificial studs comprise tubes such that the transmitter and the receiver remain exposed in the first and second cavities while the lead frame, the semiconductor die structure, and the wire bonds are encapsulated in the molding compound. In some examples, the first and second sacrificial studs cover the transmitter and receiver, respectively, such that no part of the transmitter and the receiver is exposed.

In some examples, the first and second sacrificial studs comprise metal, and removing the first and second sacrificial studs comprises etching the metal with an etching chemical chosen to etch the metal without damaging the transmitter, the receiver, and the molding compound. In some examples, the first and second sacrificial studs comprise a plastic or photoresist, and removing the first and second sacrificial studs comprises etching the plastic or photoresist without damaging the transmitter, the receiver, and the molding compound. In some examples, the first and second sacrificial studs are glued to the transmitter and the receiver with an adhesive, and are removed using a solvent to remove the adhesive from the transmitter and the receiver. The solvent is chosen to remove the adhesive without damaging the transmitter, the receiver, and the molding compound.

### BRIEF DESCRIPTION OF THE DRAWINGS

FIG. 1 illustrates an example light detection and ranging (LIDAR) system.

FIG. 2 illustrates an example overview of a sensor package molding process.

FIGS. 3A-H illustrate an example fabrication process for a sensor package molding.

FIG. 4 illustrates an example sensor package molding with a multi-chip module.

FIG. 5 illustrates example shapes of sacrificial studs used in fabricating a sensor package molding.

### DETAILED DESCRIPTION

The sensor package manufacturing processes described herein include placing sacrificial studs to prevent flow of the molding compound over the transmitter and receiver and to create a local cavity for the transmitter and receiver channels. The sacrificial studs enable massively parallel creation of cavities, as an entire lead frame with a very large number of semiconductor dies can be processed at once. The molding compound forms a barrier between the transmitter and receiver channels, improving channel isolation. The sacrificial studs are then removed to expose the transmitter and the receiver. Thus, the resulting sensor package can be made with standard equipment and manufacturing reliability. Also, a wide variety of sizes and shapes of the cavities for the transmitter and receiver channels can be made with only minor adjustment to the manufacturing process.

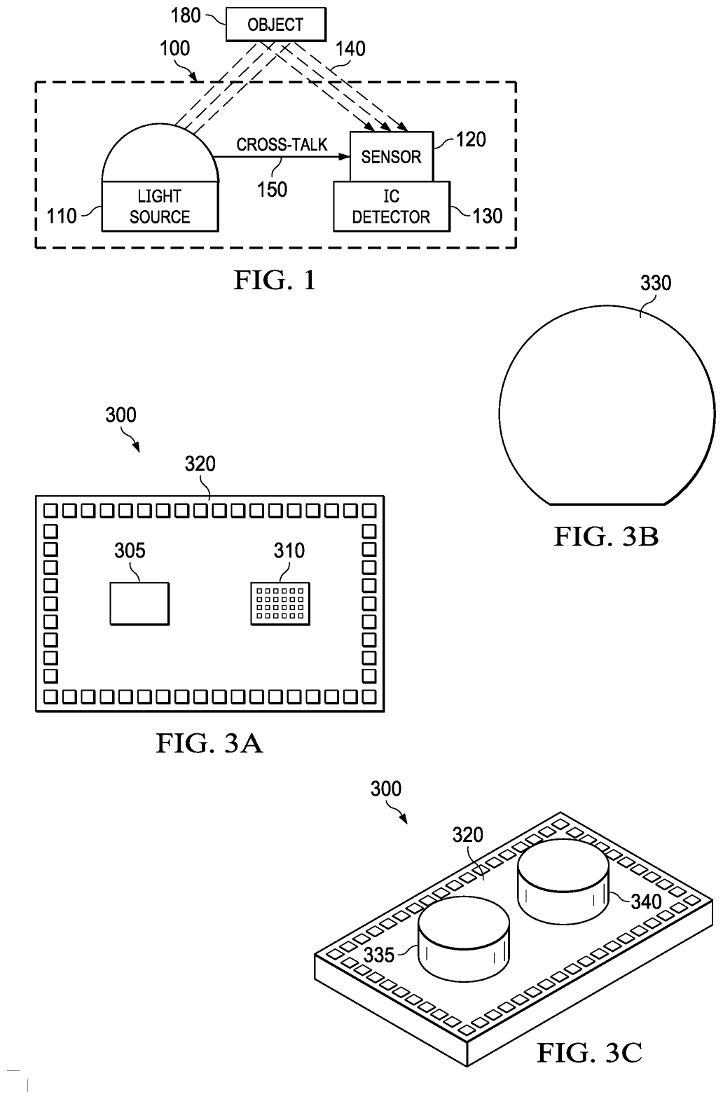

FIG. 1 illustrates an example light detection and ranging (LIDAR) system 100, which includes a light source 110, a sensor 120, and an integrated circuit (IC) 130 including a detector. The light source 110 emits light rays 140 that reflect off an object 180 and are collected by sensor 120. The distance between the LIDAR system 100 and the object 180 can be determined based on the data provided to IC detector 130 from sensor 120. Without a barrier between sensor 120 and light source 110, light rays 150 travel directly from light source 110 to sensor 120 and introduce crosstalk into the sensor data, introducing error into the distance determination. To reduce crosstalk and isolate the light transmitter and light receiver channels, a barrier is often placed between the light source 110 and sensor 120.

However to accurately determine distances, the light source 110 and the sensor 120 must be precisely located relative to each other and remain fixed, so the LIDAR system 100 does not need to perform extensive calibration more than once. To combine the light source 110 and sensor 120 into a single package, two hollow chambers are molded. A semiconductor die with the light source 110 is placed into one chamber, and a semiconductor die with the sensor 120 is placed into the other chamber. Both are wire bonded to the substrates within the chambers. Then the hollow chambers are filled with a transparent mold compound, which covers both semiconductor dies and protects the wire bonding while still allowing light to be emitted and received by the light source 110 and the sensor 120.

The combination of two different mold compounds and substrates with different properties causes manufacture of the two hollow chambers in a single package to be unreliable. To improve the manufacturability, the dies are placed farther apart, and the overall package size increases. While a LIDAR system 100 with a light source 110 and a sensor 120 is described in FIG. 1, any system with a transmitter channel and a receiver channel, such as radar systems and ultrasonic sensing systems, balances similar challenges with channel isolation, calibration, and manufacturing.

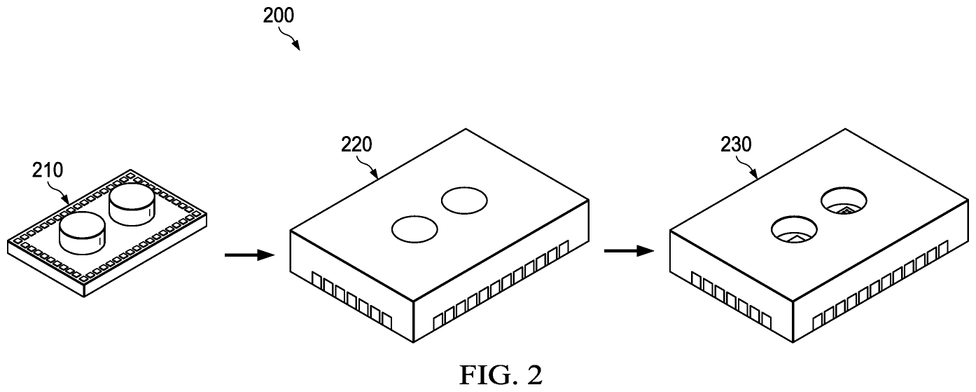

FIG. 2 illustrates an example overview of a sensor package molding process 200. Rather than separating the transmitter and the receiver onto different semiconductor dies, they are placed together on the same semiconductor die structure 210 in the desired configuration and proximity to each other. Sacrificial studs are placed over the transmitter and receiver to protect them during the next step of the molding process 200 and to create clear transmitter and receiver channels. The semiconductor die structure 210 is then encapsulated in a single standard molding compound but the sacrificial studs are left exposed, as shown in semiconductor 220. The sacrificial studs can be removed to expose the transmitter and receiver while maintaining a barrier of the molding compound between the two and ensuring channel isolation, resulting in the semiconductor die 230.

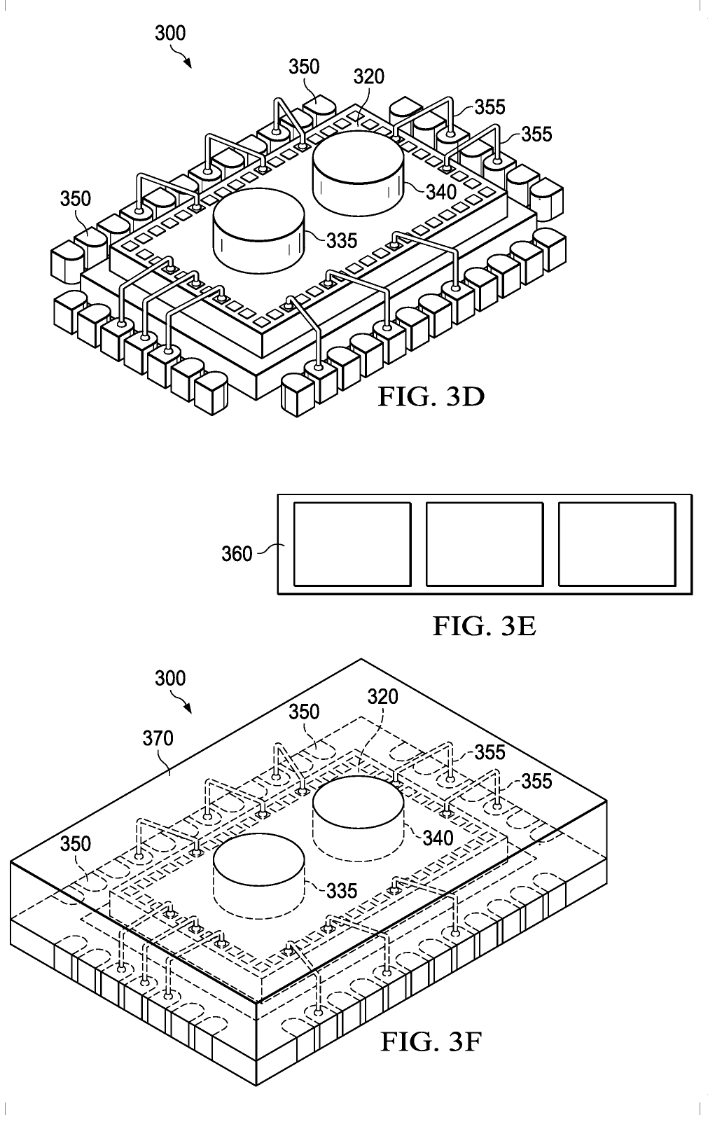

FIGS. 3A-H illustrate an example fabrication process for a sensor package molding. FIG. 3A illustrates an example semiconductor die 300 including a transmitter 305 and a receiver 310 affixed on a die 320. The transmitter 305 and receiver 310 are arranged on a die 320 in a desired configuration based on the intended implementation for the sensor package. The desired configuration can be chosen to simplify calibration procedures, increase the number of channels in an area on the die 320, or the like. FIG. 3B illustrates an example wafer 330 with multiple dies 320 fabricated together. Next, sacrificial studs 335 and 340 are placed over transmitter 305 and receiver 310, as illustrated in the angled view of semiconductor die 300 shown in FIG. 3C.

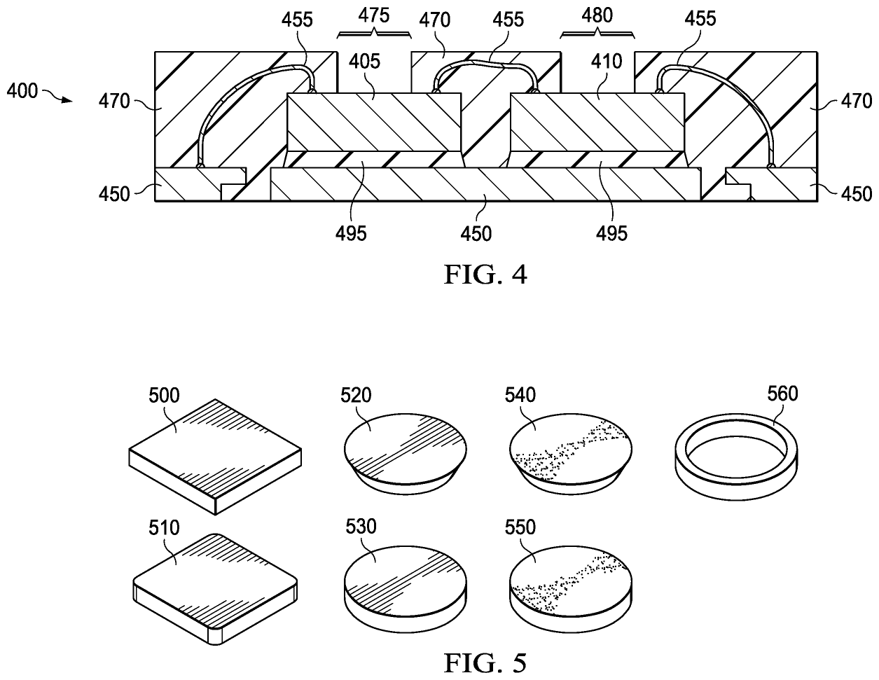

Sacrificial studs 335 and 340 are cylindrical shaped in this example, but may be hollow rings encircling transmitter 305 and receiver 310, or other shapes as shown in FIG. 5. Sacrificial studs 335 and 340 can be made of metal, plastic, photoresist, or other appropriate materials and fastened to semiconductor die 300 by an adhesive material, surface mount technology, or the like. The sacrificial studs can be fabricated using standard mold tooling, equipment, materials, and processes without resorting to special mold tooling or inserts. Also, the sacrificial studs can be created in parallel for each semiconductor die on wafer 330 such that the manufacturing process is not unduly slowed by the step of creating the sacrificial studs.

The semiconductor die 300 is separated from the larger wafer 330 by a diamond saw, a laser, or other process, and attached to a lead frame 350 and wire bonded 355, as shown in the closeup in FIG. 3D. FIG. 3E illustrates the larger array 360 of multiple semiconductor dies 300 attached to the lead frame 350. In some manufacturing processes, the sacrificial studs 335 and 340 can be placed after semiconductor die 300 is attached to the lead frame 350 and wire bonded 355. In some implementations, stress buffers and coatings such as polyimide, polybenzoxazole, and silicone coatings can be applied.

FIG. 3F shows an x-ray view of the single semiconductor 300 after it has been encapsulated in a molding compound 370 such as plastic or epoxy. The sacrificial studs 335 and 340 act as barriers for mold flow and create a local cavity without the molding compound 370. The sacrificial studs 335 and 340 are removed next, such as by chemical etching for metallic studs or light exposure for photoresist studs. A solvent can remove any remaining adhesive as needed. The material of sacrificial studs 335 and 340, molding compound 370, transmitter 305 and receiver 310, and the removal materials are chosen to ensure that the sacrificial studs 335 and 340 can be removed without damaging transmitter 305 and receiver 310 and leaving the molding compound intact.

FIG. 3G shows an x-ray view of the semiconductor die 300 with sacrificial studs 335 and 340 removed, leaving behind cavities 375 and 380, respectively, and exposing transmitter 305 and receiver 310. The cavities 375 and 380 allow transmitter 305 and receiver 310 to transmit and receive signals while a barrier of the molding compound 370 between transmitter 305 and receiver 310 ensures channel isolation between the two. The cavities 375 and 380 can be left empty or filled with a transparent plastic or other material that allows signals to be emitted and received unimpaired. In some implementations, lenses or other optical components can be aligned with the cavities 375 and 380.

The individual packages can be separated from the lead frame 350 and calibrated for use, such as for use in a proximity sensor. Because the transmitter 305 and receiver 310 are fixed relative to each other, calibration can be performed less frequently and more simply than in other systems in which the transmitter 305 and receiver 310 are on separate semiconductor die and can move relative to each other. The semiconductor die 300 as packaged is attached to a printed circuit board 390 and integrated into a larger system, as shown in FIG. 3H. For example, the semiconductor die 300 is incorporated into a proximity sensor or a LIDAR system 100, shown in FIG. 1.

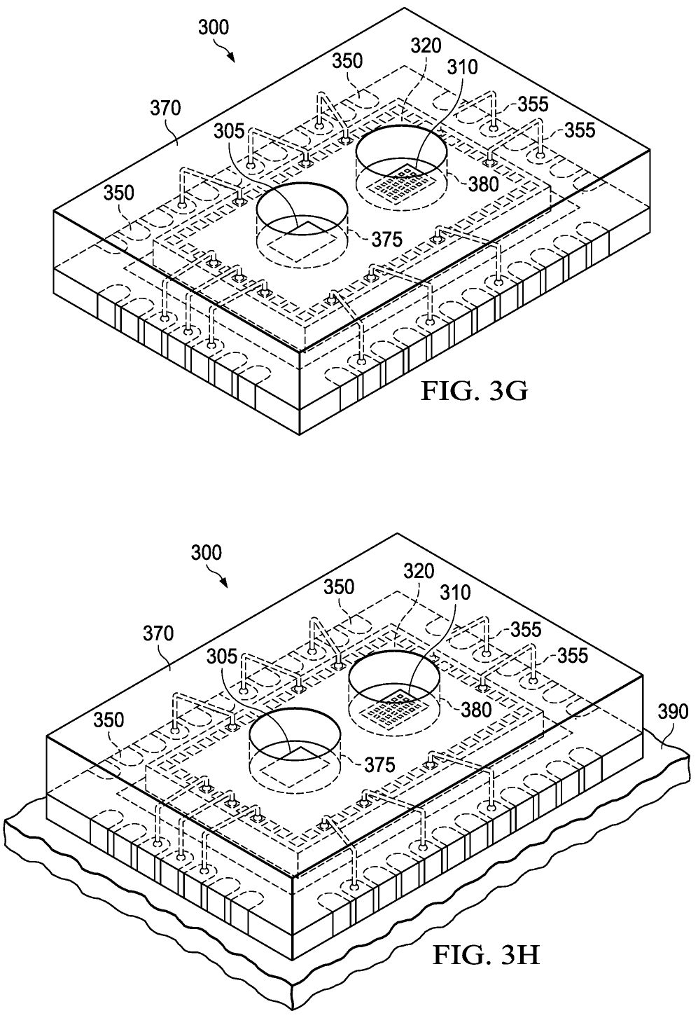

FIG. 4 illustrates an example sensor package 400 with a multi-chip module. In some implementations, the desired substrate characteristics for the transmitter and the desired substrate characteristics for the receiver are incompatible, such that the transmitter and the receiver are placed on separate semiconductor die with different characteristics. The separate semiconductor die are included in a single semiconductor die structure. The transmitter die 405 and the receiver die 410 can be packaged as a multi-chip module according to the process outlined in FIGS. 3A-H. Transmitter die 405 and receiver die 410 are fastened to a lead frame 450 by an adhesive 495 and wire bonded 455 together and to the lead frame 450.

The semiconductor die structure including the two dies 405 and 410 and the wire bonds 455 are encapsulated in molding compound 470, although cavities 475 and 480 remain open and create isolated channels for transmitter die 405 and receiver die 410. Although the relative positions of transmitter die 405 and receiver die 410 will not be as precise as the transmitter 305 and receiver 310 on a single semiconductor die 300, calibration of sensor package 400 can be done easily and once after manufacturing and performed rarely after that initial calibration.

FIG. 5 illustrates example shapes of sacrificial studs 500-560 used in fabricating a sensor package molding. The sacrificial studs can be square-shaped, as illustrated by stud 500 with pointed corners and stud 510 with rounded corners. Studs 520 and 540 are circular-shaped with tapered sides, such that the top surface of the studs is larger than the bottom surface. Similarly, studs 530 and 550 are cylindrical, with flat sides and substantially equal-sized top and bottom surfaces. Studs 520 and 540 and studs 530 and 550 are similarly shaped but made of different materials, such as metal and photoresist, respectively. While these example studs are solid, the sacrificial studs 500-550 can also be hollow rings, such as stud 560.

Modifications are possible in the described embodiments, and other embodiments are possible, within the scope of the claims.

What is claimed is:

1. A packaged integrated circuit (IC), comprising:
a lead frame;
one or more semiconductor dies on the lead frame, the one or more semiconductor dies including a first circuit and a second circuit; and
a molding compound encapsulating the lead frame and the semiconductor die, the molding compound including a first cavity over the first circuit and a second cavity over the second circuit, in which at least one of the first or second cavities includes a second material different from the molding compound.

2. The packaged IC of claim 1, wherein the one or more semiconductor dies includes a first semiconductor die and a second semiconductor die, the first circuit is in the first semiconductor die, and the second circuit is in the second semiconductor die.

3. The packaged IC of claim 1, wherein the one or more semiconductor dies includes a single semiconductor die, the first circuit and the second circuit are in the single semiconductor die.

4. The packaged IC of claim 1, wherein the molding compound is a first molding compound, and the second material includes a second molding compound.

5. The packaged IC of claim 1, wherein the first circuit includes a light transmitter, the second circuit includes a light receiver, and the second material transmits light.

6. The packaged IC of claim 1, wherein the first circuit includes a transmitter, and the second circuit includes a receiver.

7. The packaged IC of claim 1, wherein at least one of the first circuit and second circuit is part of a proximity sensor.

8. The packaged IC of claim 7, wherein the proximity sensor is calibrated to determine relative positions between the first and second circuits.

9. The packaged IC of claim 1, wherein the molding compound provides a barrier between the first and second cavities.

10. The packaged IC of claim 1, wherein each of the first and second cavities have a respective tapered wall.

11. The packaged IC of claim 1, wherein each of the first and second cavities have a respective polygon footprint or a respective circular footprint.

12. The packaged IC of claim 1, further comprising wire bonds coupled between the one or more semiconductor dies and the lead frame, and the wire bonds are encapsulated by the molding compound.

13. The packaged IC of claim 1, further comprising one or more optical components aligned with the first and second cavities.

14. The packaged IC of claim 1, wherein the first and second cavities are formed by sacrificial studs.

15. The packaged IC of claim 1, wherein the first and second cavities are formed by sacrificial rings.
